(19) United States
(12) Patent Application Publication
(10) Pub. No.: US 2002/0109614 A1
(43) Pub. Date: Aug. 15, 2002

(54) Multi-function key

(75) Inventor: Seung Kil Kim, Chapel Hill, NC (US)

Correspondence Address: David E. Bennett, Coats & Bennett, P.L.L.C., 1400 Crescent Green, Suite 300, Cary, NC, 27511, US

(73) Assignee: Ericsson Inc.

(21) Appl. No.: 09/748,039

(22) Filed: Dec. 22, 2000

(51) Int. Cl. H03M 11/00; H03K 17/94

(52) U.S. Cl. 341/23; 379/369

(57) ABSTRACT

A multi-function keyboard in which at least some of the individual keys are actuable in a first mode in which a single character is displayed, and a second mode in which a first, a second or a third character is displayed. A switch permits selection of the desired mode which activates different key press click sounds depending on mode of operation..

This invention relates to keys and keyboards for alpha-numeric data entry. The invention has particular utility for use in mobile communication terminals, and will be described in connection with such utility, although other utilities are contemplated.

### BACKGROUND OF THE INVENTION

Mobile terminals often utilize keys for the entry of data. The data to be inputted typically is in the form of characters, e.g. English letters A-Z; numbers, e.g. Arabic numbers 0-9, and various punctuation and function symbols or signs, e.g. “pound” and “star” keys. As technology has advanced and electronic circuits have been miniaturized, these mobile terminals have significantly deceased in overall size. In mobile terminals utilizing keys for data entry, certain industry standards have evolved relating to the layout, size and spacing of input keys. For example, a typical cellular radiophone comprises a 3×4 standard telephone key layout, plus the usual function keys, e.g. on-off, volume, etc. If the keys are too small or too close together, the user may encounter difficulty in actuating a particular key. The size, quantity, and spacing between the data entry keys play a significant role in determining the overall size of the terminal.

Technology has also increased the capabilities of these mobile terminals. Some mobile terminals have the ability to make phone calls, surf the World Wide Web, send and receive text and voice messages, and access remote databases. To permit access to these several capabilities, some manufacturers have increased the quantity of input keys. Other manufacturers have developed complicated schemes that require the user to actuate keys in a predetermined sequence, actuate the same key a plurality of times, or actuate multiple keys simultaneously in order to enter specific data or access a desired function. Some of these complicated schemes also may require the user to use more than one hand. And, remembering these complicated schemes may frustrate a typical user in an emergency situation, and the inability to recall the proper scheme may lead to needless delays.

### BRIEF SUMMARY OF THE INVENTION

In accordance with the present invention there is provided a keyboard comprising a plurality of multi-function keys. The keyboard is capable of being manually or automatically toggled between a first mode and a second mode. In the first mode a first character is inputted regardless of how a key is actuated, while in the second mode, a first, a second or a third character is inputted depending on the direction the key is actuated.

### BRIEF DESCRIPTION OF THE DRAWINGS

For a better understanding of the present invention, together with other objects, features and advantages, reference should be made to the Detailed Description of the Invention which should be read in conjunction with the following figures wherein like numerals depict like elements and in which:

FIG. 1 is a top plan view of a mobile terminal made in accordance with the present invention;

FIG. 2 is a top view of a first embodiment of a single actuator made in accordance with the present invention;

FIGS. 3A-3C are side cross-sectional views of the actuator of FIG. 2;

FIG. 4 is a flow chart illustrating input of data using the mobile terminal of FIG. 1 of the present invention;

FIG. 5 is a top view of a second embodiment of an actuator made in accordance with the present invention;

FIGS. 6A-6C are cross sectional views of the actuator of FIG. 3;

FIG. 7 is an exploded view of a typical dome switch contact pad on a circuit board; and

FIG. 7A-7C are cross sectional views of an actuator incorporating a dome switch contact pad of FIG. 7.

### DETAILED DESCRIPTION OF THE INVENTION

The present invention is described herein in the context of a mobile terminal. As used herein, the term “mobile terminal” may include a cellular radiotelephone with or without a multiline display; a Personal Communications System (PCS) terminal that may combine a cellular radiotelephone with data processing, facsimile and data communications capabilities; a PDA that can include a radiotelephone, pager, Internet/intranet access, Web browser, organizer, calendar and/or a global positioning system (GPS) receiver; and a conventional laptop and/or palmtop receiver or other appliance that includes a radiotelephone transceiver. Mobile terminals may also be referred to as “pervasive computing” devices.

In addition, the present invention is described herein in the context of a GSM cellular communication system. While the present invention may be particularly useful for improving the performance of GSM cellular networks, it should be understood that the principles of the present invention maybe applied to any cellular or wireless system utilizing other air interfaces, such as TDMA, CDMA or FDMA. It should be further understood that the principles of the present invention may be utilized in hybrid systems that are combinations of two or more of the above air interfaces. In addition, a mobile terminal, in accordance with the present invention, may be designed to communicate with a base station transceiver using any standard based on GSM, TDMA, CDMA, FDMA, a hybrid of such standards or any other standard.

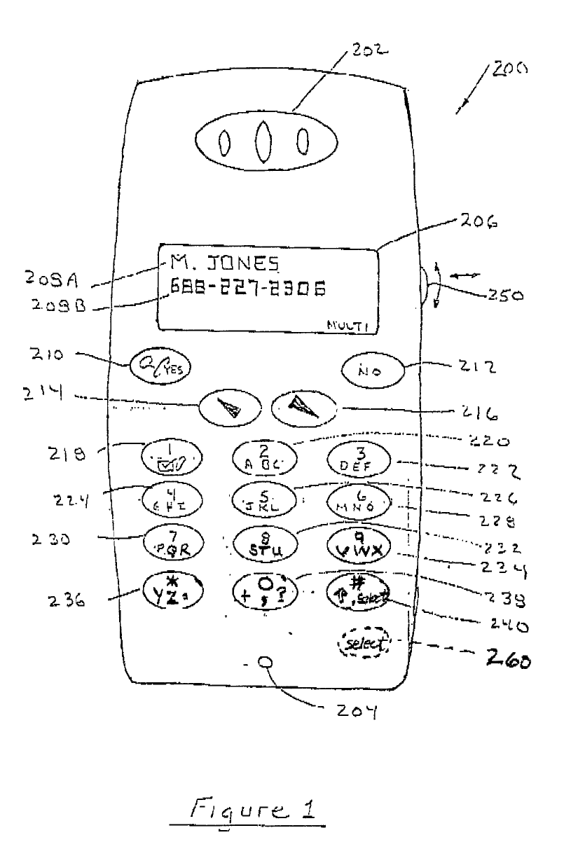

FIG. 1 shows a top view of an embodiment of a mobile terminal 200 made in accordance with the present invention. The mobile terminal 200 is shown as a cellular radiophone. The mobile terminal has a speaker 202, a microphone 204, a display 206, a scroll actuator 250, and a plurality of keys 210-240. The display 206 may be capable of displaying one or several lines of characters. Each of the keys 210-240 has indicia associated therewith. The indicia may be located on or adjacent the key. By way of example, referring to FIG. 2, each key, e.g. key 220 may include several indicia, 22, 24, 26 and 28. Certain keys, e.g. keys 212, 214, and 216 may be capable of generating only one signal, while the remaining keys may be capable of generating more than one signal as will be described in detail hereinafter. For example, key 220 when actuated can generate a “2” when the mobile terminal is in operation single mode and an “A”, “B”, or “C” when the mobile device is in multi-mode operation.

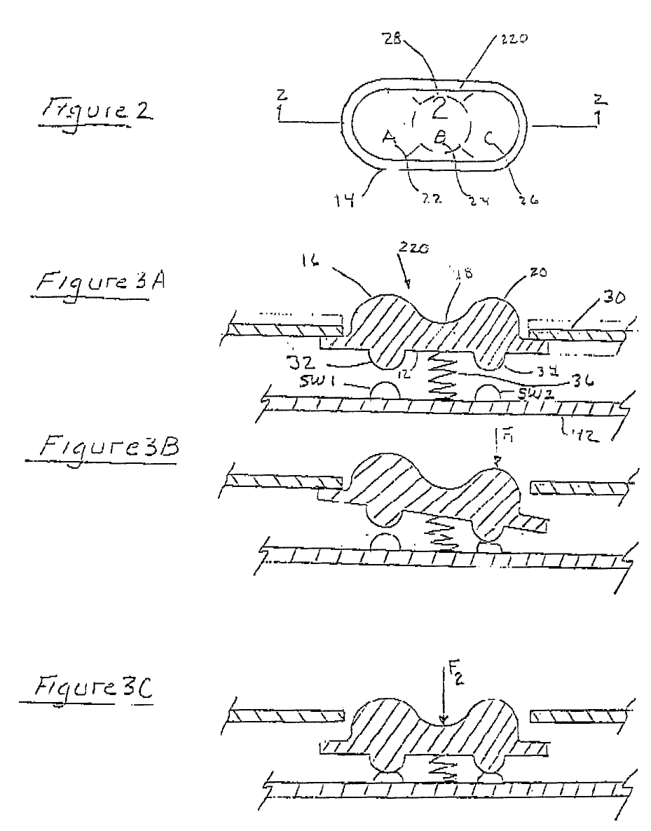

Referring also to FIGS. 3A-3C, in a first embodiment key 220 comprises an oval-shaped button captured in an opening 14 formed in the front surface 30 of terminal 200. Key 220 has a contoured top surface with three regions 16, 18, and 20. Region 18 is a concave and is centrally located between two convex regions 16 and 20. Regions 16, 18, 20 are shown as quasi-or semispherical, but are not limited to quasi-or semi-spherical shapes.

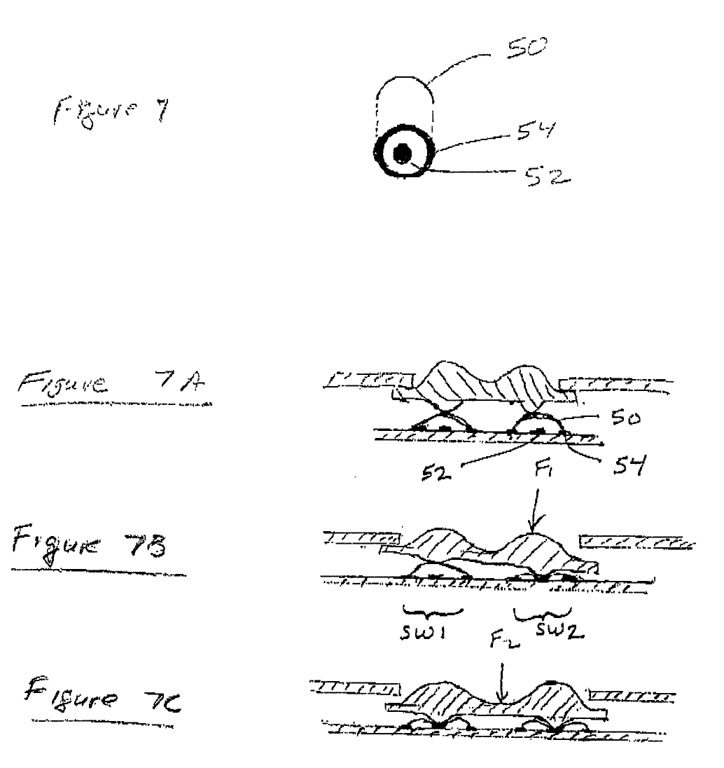

As seen in FIGS. 3A-3C, key 220 is spaced a distance from a circuit board 42. The circuit board 42 may contain electrical and mechanical components joined by conductive traces that form an electrical circuit. One of the electrical components may include a microcontroller with stored software or firmware for performing applications. Coupled to the conductive traces on the printed circuit board are switches SW1 and SW2. Switches SW1 and SW2 are designed to be actuated by protrusions 32 and 34 formed on the bottom surface 12 of key 220. Referring to FIGS. 7A-7C, switches SW1 and SW2 may be metal dome switches 50 that provide tactile feed back to the user and make electrical contact between an outer ring 52 and a central conductor contact pad 54 on the circuit board, when pressed down. Switches SW1 and SW2 typically have minimum actuation force requirements. Application of a force in excess of this minimum force requirement changes the state of the contacts in the switches SW1 and SW2 from “open” to “closed”. Upon removal of the force, the contacts return to their original state. A resilient member 36 such as a compression spring coupled between the bottom surface 12 of key 220 and the top surface of the circuit board 42 biases the key 220 away from the circuit board 42. Alternatively, the dome switch 50 itself can provide sufficient spring force, so that a separate resilient member may not be needed.

FIG. 3A shows a side view of key 220 in a “neutral” position; i.e. the protrusions 32 and 34 are spaced from the switches SW1 and SW2 respectively. When a user applies a sufficient amount of force to key 220 to overcome the force provided by the resilient member 36, key 220 is moved towards the printed circuit board 42.

FIG. 3B shows the result of a user applying a sufficient force F1 to region 20 of key 220 to overcome the force of the resilient member 36 and the minimum actuation force of switch SW2. Although the force is shown perpendicular to the front surface 30, forces applied at angles other than perpendicular that urge switch 40 to be actuated are considered equivalent. The protrusion 34 on the bottom surface 12 of key 10 couples the force F1 to the switch SW2. When actuated, the contacts in switch SW2 alternate their state. An electrical circuit coupled to the switch SW2 detects a change in the state of the contacts in switch SW2. Similarly, application of force to region 16 would urge protrusion 32 to actuate switch SW1. When metal dome switch itself is used as the resilient member, its operation is shown in FIGS. 7A-C. FIG. 7A shows a metal dome switch 50 in a “neutral” position. When actuated, metal dome 50 deforms e.g. as shown in FIG. 7B and its center makes a contact to with the central conductor contact pad54 on the circuit board closing switch SW2. When both metal dome keys are pressed simultaneously, both SW1 and SW2 are closed as shown in FIG. 7C.

FIG. 3C shows the result of the user applying a sufficient force F2 to region 18 of key 220 to overcome the force of the resilient member 36 and the minimum actuation force of switches SW1 and SW2. Protrusions 32 and 34 on the bottom surface 12 of key 220 couple the force F2 to switches SW1 and SW2. Similarly, an electrical circuit coupled to the switches SW1 and SW2 detects a change in the state of the contacts in switches SW1 and SW2.

Key 220 has been shown having protrusions 32 and 34 on the bottom surface 12 for actuating mechanical switches SW1 and SW2. Alternatively, the protrusions 32 and 34 may take the form of conductive pads and switches SW1 and SW2 may comprise conductive traces on the circuit board. When the key is actuated by a user, the conductive pads on the bottom surface of the key come in contact with the conductive traces on the circuit board and complete an electrical circuit by coupling the conductive traces on the circuit board. If desired, this type of switch configuration may include separate means for providing tactile feedback to the user.

In the above embodiment, key 220 has been shown as an individual key captured in the opening 14 and spaced from the circuit board 42 by a resilient member 36. In actuality, a plurality of keys can conveniently be captured by a single web. The web can be molded, stamped or machined out of a suitable material. The web can perform two or more functions. For example, the web can perform the dual functions of capturing the keys, and also serve to keep dust and moisture from the circuit board.

The keys shown in FIG. 2 and 3A-3C are mechanically tiltable in a plurality of different positions. Each of the different positions inputs a unique, predetermined signal. When the key is tilted to the left, a first input is generated; when the key is tilted to the right, a second input is generated; and, when the key is actuated straight down, a third signal is generated. The coupled electrical circuit is capable of decoding these inputs and displaying a character (letter, number, symbol, or punctuation sign) in a display, storing a character in memory, transmitting a character over a wired or wireless network, performing an associated function, and/or generating an audible tone. The remainder of this disclosure will simply refer to “displaying” a character. Thus, when reference is made to displaying a character, it should be understood that the coupled electrical circuit could alternatively be storing a character in memory, transmitting a character over a wired or wireless network, performing an associated function, and/or generating an audible tone.

The electrical circuit and associated software in the terminal determines which character is displayed based on (1) which key is actuated, (2) whether the mobile terminal is in a single mode or in a multi-mode, and (3) if in the multi-mode, how the key is actuated. Also, different key press “click” sounds is may be generated depending on mode. When key is operated in a multi-mode, a different key “click” sound is generated from a single mode operation. Thus, a user can differentiate mode of operation by hearing key “click” sound and this helps a user to operate the keys in a proper mode. By way of example, in the embodiment shown in FIG. 1, if the mobile terminal is in the multi-mode and key 220 is tilted to the left, the character “A” is displayed; if key 220 is tilted to the right the character “C” is displayed; and, if key 220 is actuated straight down, the character “B” is displayed. In the single mode, the same character, i.e. the numeral “2”, is displayed regardless of how the key is actuated.

The terminal can be toggled between the single mode and the multi-mode either manually or automatically. Since each key can display up to three (3) characters when the terminal is multi-mode, and can display one (1) character when the terminal is in the single mode, the number of characters that can be displayed from a single key is increased 4-fold compared to a conventional single-mode key. By the same token, then number of keys required to display “X” number of characters can be reduced 4-fold as compared to a conventional key board comprising only single mode keys. As a result, the present invention permits, for example, a conventional 3×4 cellular radiophone keyboard to be used to display, in addition to the usual 10 Arabic numerals, pound and star, all of the common letters of the English alphabet, plus a certain number of punctuation marks and other functions.

Referring again to FIG. 1, certain actuators, for example actuators 210-216 may be designed to always operate in a single mode regardless as to whether the keyboard is selected to operate in single mode or multi-mode.

There are several ways to manually toggle a mobile terminal from the single mode to the multi-mode. One specific key, shown in phantom at 260 in FIG. 1, can be designated as “mode”. This will add one more key, but may be a less confusing solution to the user. Another way is to assign a mode “select” function as a part of multi-functions to a single key. The user presses mode select key 240 to the right. This toggles the terminal to switch from single mode to multi-mode and displays the multi-mode. Once in multi-mode, the multi-mode status is displayed on display 206, and the various multi-function keys may be used to select one of three letters, punctuation signs or functions. To facilitate selection between modes, key 240 may be adapted to provide only three functions, mode selection function, # and shift functions. In such case the pound sign function which typically is used frequently may be always available to the user, by pressing the key straight down. To return to single mode, the user merely needs to again press the select key 240 to the right. This returns all of the keys to single mode function. Key 240 is unique key which has two functions in a single mode. When pressed in center, it operates as “#” key. If a user presses at left or right, it operates as mode “select” key and switches mode. “Shift” function only works in a multi-mode. In a single mode, “shift” function works as mode “select” function, not as “shift” function. This is to make the mode “select” function less confusing to a user in a single mode.

The mode also can be toggled automatically. By way of example, in one embodiment of the terminal, the terminal may automatically set in the either the single mode or the multi-mode when the terminal is turned on, either by a design default setting, or by user defined default setting. Many terminals have the ability to run a plurality of applications, which may be software and/or firmware based, and accept and process data entered through a keyboard. Certain applications typically require the entry of more letters than numbers, for example, a text messaging application, while other applications typically require the entry of more numbers than letters, for example, a phone or voicemail, or a calculator application. By way of example, for use in a cellular radiotelephone, the terminal may automatically or default set to the single mode. Thus, when the terminal is turned on, the mode function automatically sets to single mode, and when the user actuates one of the keys 220-234 or 238, a number is displayed. The user can manually toggle between modes by actuating the mode actuator 240.

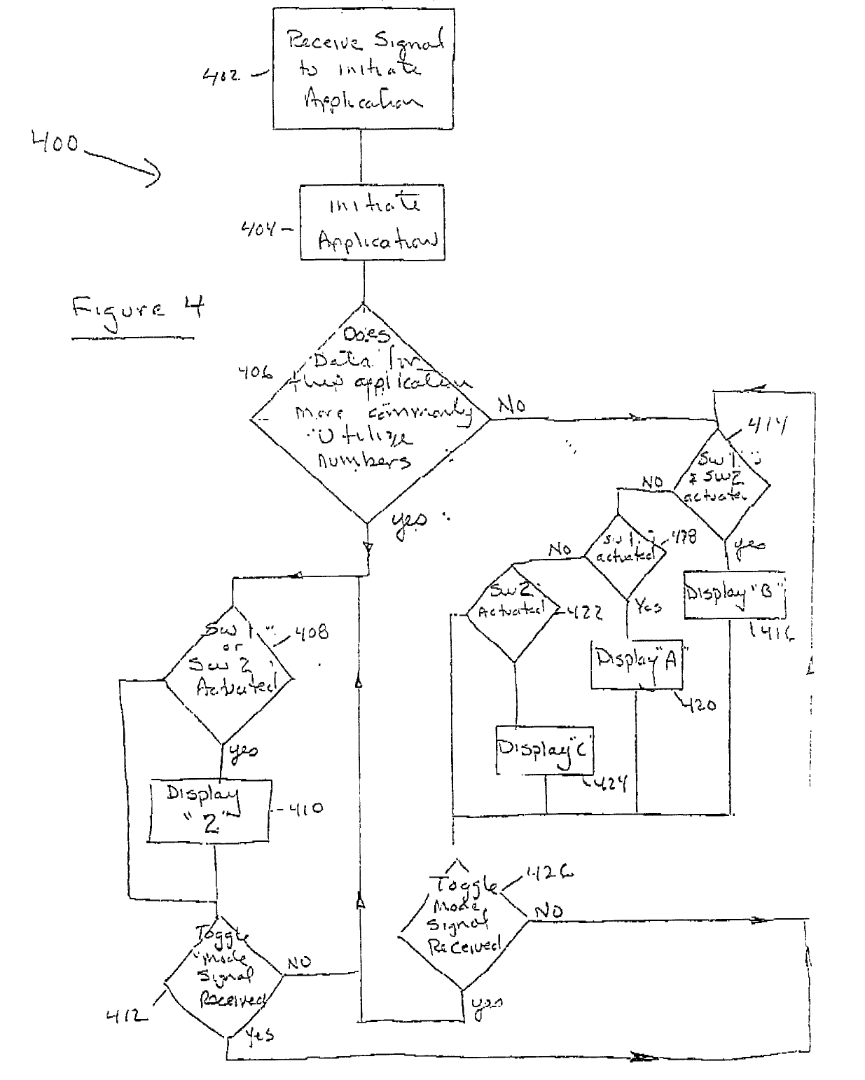

FIG. 4 shows a flowchart 400 consistent with the present invention. The flowchart 400 reflects the terminal response to actuation of keys on the terminal for example switches SW1 and SW2 by key 220 as described above. When the mobile terminal receives a signal to initiate an application at step 402, the terminal initiates the application at step 404. At step 406, the terminal determines if the application initiated is single-or multi-mode, i.e. numbers or letters. If single mode, i.e. numbers were initiated, the terminal proceeds to step 408. At step 408 the terminal determines if a switch SW1 or SW2 has been actuated. If the terminal determines that either switch has been actuated, the terminal displays a first character in the display, for example, the numeral “2”. The terminal then proceeds to step 412 where the terminal determines if a toggle “mode” signal is received. If at step 408, no switch has been actuated, the terminal proceeds to step 412. If at step 412, a toggle “mode” signal is received, the terminal proceeds to step 414, otherwise it returns to step 408.

At step 406, if the terminal determines that the application initiated is multi-mode, e.g. letters, the terminal proceeds to step 414. At step 414, the terminal determines if the switches SW1 and SW2 have been simultaneously actuated. If the terminal determines that both switches were simultaneously actuated, the terminal displays a second character in the display at step 416, for example, the letter “B”. If both switches were not actuated, the terminal proceed to step 418 were the terminal determines if switch SW1 has been actuated. If the terminal determines that switch SW1 has been actuated, the terminal displays a third character in the display, for example, the letter “A”. If switch SW1 was not actuated, the terminal proceeds to step 422 were the terminal determines if switch SW2 has been actuated. If the terminal determines that switch SW2 has been actuated, the terminal displays a fourth character in the display, for example, the letter “C”. The terminal then proceeds to step 426 where the terminal determines if a toggle “mode” signal is received. If a toggle “mode” signal is received, the terminal proceeds to step 408, otherwise it returns to step 414. This flowchart illustrates a general operational concept, but does not necessarily show complete operation for all key functions as a flowchart.

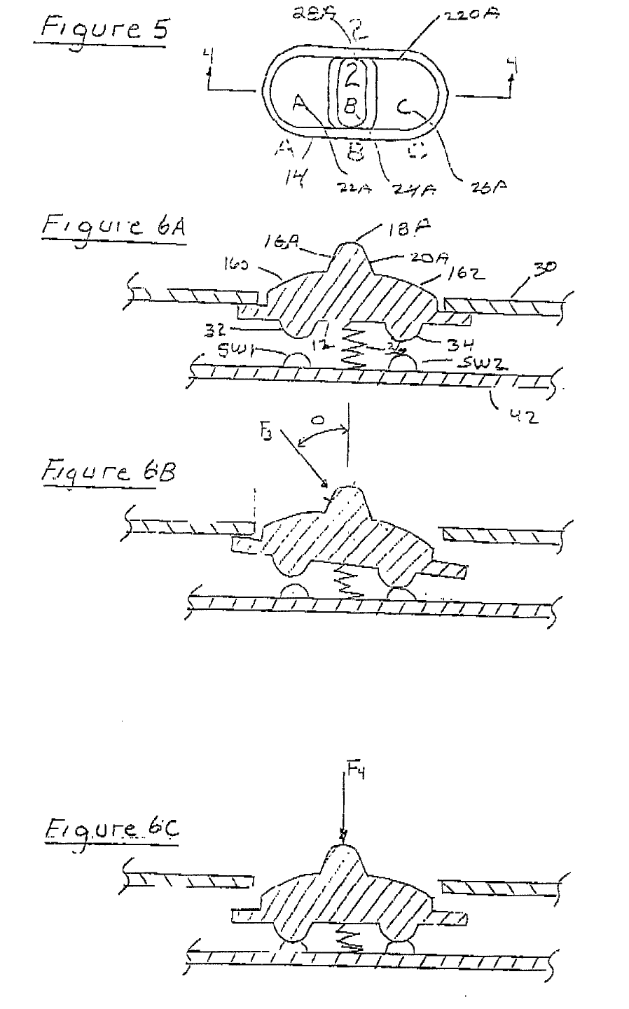

The invention is subject to modification. For example, referring to FIGS. 5 and 6A-6C, there is illustrated an alternative embodiment of key 220A in accordance with the present invention. As before, key 220A is captured in an opening 14 formed in the front surface 30 of a terminal. Key 220A has a contoured top surface including a protrusion having regions 16A, 18A and 20A. The top surface of key 220A includes several indicia 22A, 24B, 26A and 28. The indicia alternatively can be located adjacent key 220A on the front surface 30 of the terminal, i.e. as shown in phantom. As before, key 220A is spaced a distance from a circuit board 42 which contains electrical and mechanical components joined by conductive traces (not shown) that form an electrical circuit. As before, one of the electrical components may include a microcontroller with stored software or firmware for performing applications. Coupled to conductive traces on the circuit board are switches SW1 and SW2. Switches SW1 and SW2 are designed to be actuated by protrusions 32 and 34 formed on the bottom surface 12 of key 220A. Switches SW1 and SW2 may be dome switches that provide tactile feed back to the user. Switches SW1 and SW2 typically have minimum actuation force requirements. Application of a force in excess of this minimum force requirement changes the state of the contacts in the switches SW1 and SW2,—from “open” to “closed” or “closed”. Upon removal of the force, the contacts return to their original state. A resilient member 36 such as a mechanical compression spring coupled between the bottom surface 12 of key 220A and the top surface of the circuit board 42 biases the key 220A away from the circuit board 42. When the metal dome switch itself is used as a spring, no other resilient member is required. In such case, protrusions 32 and 34 touch the surface of SW1 and SW2 at “neutral” position. Thus there is no gap between the protrusions and the surface of the dome switch SW1 or SW2. This provides more “snappy action” of dome switch.

FIG. 6A shows a side view of key 220A in a “neutral” position; i.e. the protrusions 32 and 34 are spaced from the switches SW1 and SW2 respectively. When a user applies a sufficient force to key 220A to overcome the force provided by resilient member 36, key 220A may be moved towards the circuit board 42.

FIG. 6B shows the result of a user applying a sufficient force F3 to region 16A of the key 220A to overcome the force of the resilient member 36 and the minimum actuation force of switch 140. The force F3 is shown as a force at angle θ to the normal and is directed towards the switch to be actuated. This force urges key 220A to tilt downward on the right-hand side. The protrusion 34 on the bottom side of key 220A couples the force F3 to the switch SW2. When actuated, the contacts in switch SW2 alternate their state. An electrical circuit coupled to the switch SW2 detects a change in the state of the contacts in switch SW2. Similarly, application of force applied to region 20A at angle θ urges protrusion 32 to actuate switch SW1.

FIG. 6C shows the result of a user applying a sufficient force F4 to region 18A of key 220A to overcome the force of the resilient member 36 and the minimum actuation force of switches SW1 and SW2. Protrusions 32 and 34 on the bottom surface 12 of key 220A couple the force F4 to switches SW1 and SW2. Similarly, an electrical circuit coupled to the switches SW1 and SW2 detects a change in the state of the contacts in switches SW1 and SW2.

Likewise as described above, the protrusions 32 and 34 on the bottom surface 12 of key 220A can be replaced with conductive pads and switches SW1 and SW2 can be replaced with conductive traces on the circuit board, so that when the key is actuated by a user, the conductive pads on the bottom surface of the actuator come in contact with conductive traces on the circuit board 42 and complete an electrical circuit by coupling the conductive traces on the circuit board 42. Likewise as described above, key 220A can be coupled to other actuators with a web.

Key 220A is mechanically tiltable in a plurality of directions by applying a sufficient force to either of the side regions 16A or 20A or a downward force to region 18A. Each of the different positions results in the generation of a unique input.

As shown in FIG. 5, when key 220A is tilted to the left, a first input is generated; when the key is tilted to the right, a second input is generated; and, when the key is actuated straight down, a third input is generated. As before, the coupled electrical circuit is capable of decoding these inputs and displaying a character (letter, number, symbol, or punctuation) in a display, storing a character in memory, transmitting a character over a wired or wireless network, performing an associated function, and/or generating an audible tone and/or a different key press “click” sound electronically depending on the mode of operation.

Various changes and modifications of the present invention are possible in light of the above teaching. It is, therefore, to be understood that within the scope of the appended claims, the invention may be practiced otherwise than literally described, but fall within the scope therein.

1. An alpha-numeric keyboard, comprising:
a plurality of multi-function input keys actuable in a first mode in which a single character is displayed, and a second mode in which a first, a second and a third character is displayed depending upon the direction the key is actuated; and
a mode selection switch for selecting between said first and said second modes.

2. The alpha-numeric keyboard of claim 1, wherein each of said keys has a unique set of indicia associated therewith.

3. The alpha-numeric keyboard of claim 2, and further comprising distinct indicia on each key.

4. The alpha-numeric keyboard of claim 2, and further comprising distinct indicia adjacent each key.

5. The alpha-numeric keyboard of claim 2, wherein at least some of said keys have one distinct numeral and three distinct letters associated therewith.

6. The alpha-numeric keyboard of claim 1, wherein said mode selection switch is activated through a key in the keyboard.

7. The alpha-numeric keyboard of claim 6, wherein said mode selection switch activating key also serves as a character input key.

8. The alpha-numeric keyboard of claim 1, wherein at least some of said keys have a contoured top surface.

9. The alpha-numeric keyboard of claim 8, wherein said contoured top surface includes a concave region located between two convex regions.

10. The alpha-numeric keyboard of claim 8, wherein said contoured top surface comprises a central protrusion.

11. The alpha-numeric keyboard of claim 1, wherein each of said multi-function input keys has a first and a second switch element underlying said key.

12. The alpha-numeric keyboard of claim 11, wherein said keys are resiliently biased from said switch elements.

13. The alpha-numeric keyboard of claim 12, wherein said keys are resiliently biased by a spring.

14. The alpha-numeric keyboard of claim 12, wherein said keys are resiliently biased by a dome switch .

15. The alpha-numeric keyboard of claim 1, wherein said keys are captured under an apertured cover.

16. The alpha-numeric keyboard of claim 11, wherein said switch elements provide tactile feedback.

17. The alpha-numeric keyboard of claim 11, wherein said switch elements activate electrically generated click sounds.

18. The alpha-numeric keyboard of claim 11, wherein said switch elements are mounted on a circuit board underlying said keys.

19. The alpha-numeric keyboard of claim 18, and further comprising a micro-controller with stored software of firmware operatively connected to said circuit board.

20. The alpha-numeric keyboard of claim 19, wherein said micro-controller generates signals for electrically generating different key press click sounds depending on mode of operation.

21. The alpha-numeric keyboard of claim 1, and further comprising a display.

22. The alpha-numeric keyboard of claim 21, wherein said display comprises a mode indicator.

23. The alpha-numeric keyboard of claim 21, wherein said display displays the characters selected.

24. The alpha-numeric keyboard of claim 21, wherein said display comprises a multi-line display.

25. A mobile terminal comprising an alpha-numeric keyboard as claimed in claim 1.

26. The mobile terminal of claim 25, wherein said mobile terminal comprises a cellular radiotelephone.

27. The mobile terminal of claim 26, wherein the cellular radiotelephone comprises a 3×4 key layout.

28. The mobile terminal of claim 25, wherein each of said keys has a unique set of indicia associated therewith.

29. The mobile terminal of claim 28, and further comprising distinct indicia on each key.

30. The mobile terminal of claim 28, and further comprising distinct indicia adjacent each key.

31. The mobile terminal of claim 28, wherein at least some of said keys have one distinct numeral and three distinct letters associated therewith.

32. The mobile terminal of claim 25, wherein said mode selection switch is activated through a key in the keyboard.

33. The mobile terminal of claim 32, wherein said mode selection switch activating key also serves as a character input key.

34. The mobile terminal of claim 25, wherein at least some of said keys have a contoured top surface.

35. The mobile terminal of claim 34, wherein said contoured top surface includes a concave region located between two convex regions.

36. The mobile terminal of claim 34, wherein said contoured top surface comprises a central protrusion.

37. The mobile terminal of claim 25, wherein each of said multi-function input keys has a first and a second switch element underlying said key.

38. The mobile terminal of claim 37, wherein said keys are resiliently biased from said switch elements.

39. The mobile terminal of claim 38, wherein said keys are resiliently biased by a spring.

40. The mobile terminal of claim 38, wherein said keys are resiliently biased by a dome switch.

41. The mobile terminal of claim 25, wherein said keys are captured under an apertured cover.

42. The mobile terminal of claim 37, wherein said switch elements provide tactile feedback to the user.

43. The mobile terminal of claim 37, wherein said switch elements activate electrically generated click sounds.

44. The mobile terminal of claim 37, wherein said switch elements are mounted on a circuit board underlying said keys.

45. The mobile terminal of claim 44, and further comprising a micro-controller with stored software of firmware operatively connected to said circuit board.

46. The mobile terminal of claim 45, wherein said micro-controller generates signals for electrically generating different key press click sounds depending on mode of operation.

47. The mobile terminal of claim 25, and further comprising a display.

48. The mobile terminal of claim 47, wherein said display comprises a mode indicator.

49. The mobile terminal of claim 47, wherein said display comprises a character indicator.

50. The mobile terminal of claim 47, wherein said display comprises a multi-line display.
